(19) United States
(12) Patent Application Publication
(10) Pub. No.: US 2024/0402054 A1
(43) Pub. Date: Dec. 5, 2024

(54) SUBSTRATE HOLDING DEVICE AND METHOD FOR DETECTING WEAR IN SUBSTRATE HOLDING DEVICE

(71) Applicant: EBARA CORPORATION, Tokyo (JP)

(72) Inventor: Shuichi SUEMASA, Tokyo (JP)

(21) Appl. No.: 18/677,017

(22) Filed: May 29, 2024

(30) Foreign Application Priority Data
May 31, 2023 (JP) 2023-089683

(51) Int. Cl. G01M 99/00; B08B 1/14; B08B 1/20; B08B 1/34; B08B 3/04

(52) U.S. Cl. CPC G01M 99/005; B08B 1/14; B08B 1/20; B08B 1/34; B08B 3/041

(57) ABSTRACT

A substrate holding device includes at least three rotation parts each including a contact gripping part that contacts a periphery portion of a substrate and rotates the substrate, a moving mechanism moving at least one of the at least three rotation parts toward the substrate to cause a plurality of contact gripping parts to grip the substrate, a first sensor detecting a position of a moving rotation part, which is a rotation part moved by a moving mechanism, and a detection unit storing a first initial position, which is a position of the moving rotation part when the plurality of contact gripping parts grip the substrate in a state where the plurality of contact gripping parts are not worn, and detecting occurrence of wear of the contact gripping parts on the basis of a difference between a current position of the moving rotation part and the first initial position.

### TECHNICAL FIELD

The present invention relates to a substrate holding device and a method of detecting wear in a substrate holding device.

### BACKGROUND ART

Patent Document 1 discloses a substrate holding device including a plurality of spindles. Each spindle has a rotation part capable of rotating. Each rotation part is provided with a contact gripping part that comes into contact with the periphery portion of a substrate. In this substrate holding device, the substrate is held by the contact gripping parts of the plurality of spindles gripping the substrate. In this state, the substrate also rotates as each rotation part rotates. In other words, the substrate holding device of Patent Document 1 holds the substrate while rotating the substrate.

Such a substrate holding device is incorporated into, for example, a substrate cleaning device that includes a cleaning member (such as a sponge) for cleaning the substrate. The cleaning member cleans the substrate by coming into sliding contact with the substrate held and rotated by the substrate holding device.

### CITATION LIST

### Patent Documents

[Patent Document 1] Japanese Unexamined Patent Application, First Publication No. 2018-195680

### SUMMARY OF INVENTION

### Problem to be Solved by the Invention

Incidentally, as the substrate holding device continues to be used, the contact gripping part as described above is gradually worn out. Conventionally, there has been no means of detecting wear in the contact gripping part. For this reason, it has been common to perform an operation of predicting in advance a period of time during which wear will occur in the contact gripping part and replacing a rotation part when the substrate holding device has been used for the predicted period of time.

However, depending on such an operation, there is a possibility that the rotation part may be replaced too early or too late. For example, the amount of wear in the contact gripping part varies depending on conditions of use of the substrate holding device. This variation in the amount of wear makes it difficult to accurately predict when to replace the rotation part. If it is possible to detect wear in the contact gripping part, it will be possible to replace the rotation part at an appropriate time.

The present invention has been made in consideration of such circumstances, and aims to provide a substrate holding device and a method of detecting wear in a substrate holding device, capable of detecting wear in a contact gripping part for gripping and rotating a substrate.

### Means to Solve the Problem

To solve the problems described above, a substrate holding device according to an aspect 1 of the present invention includes at least three rotation parts each including a contact gripping part that contacts a periphery portion of a substrate and rotates the substrate, a moving mechanism moving at least one of the at least three rotation parts toward the substrate to cause the plurality of contact gripping parts to grip the substrate, a first sensor directly or indirectly detecting a position of a moving rotation part, which is a rotation part moved by a moving mechanism, and a detection unit storing a first initial position, which is a position of the moving rotation part when the plurality of contact gripping parts grip the substrate in a state where the plurality of contact gripping parts are not worn, and detecting occurrence of wear of the contact gripping parts on the basis of a difference between a current position of the moving rotation part and the first initial position.

To solve the problems described above, a substrate holding device according to an aspect 2 of the present invention includes at least three rotation parts each including a contact gripping part that contacts a periphery portion of a substrate and rotates the substrate, a moving mechanism moving at least one of the at least three rotation parts toward the substrate to cause the plurality of contact gripping parts to grip the substrate, a second sensor detecting a position of the substrate, and a detection unit storing second initial position, which is a position of the substrate when the plurality of contact gripping parts grip the substrate in a state where the plurality of contact gripping parts are not worn, and detecting occurrence of wear of the contact gripping parts on the basis of a difference between a current position of the substrate and the second initial position.

In addition, according to an aspect 3 of the present invention, the substrate holding device of the aspect 2 may further include a first sensor directly or indirectly detecting a position of a moving rotation part, which is the rotation part moved by the moving mechanism, in which the detection unit stores a first initial position, which is the position of the moving rotation part when the plurality of contact gripping parts grip the substrate in a state where the plurality of contact gripping parts are not worn, and the detection unit detects occurrence of wear of the contact gripping parts on the basis of a difference between a current position of the substrate and the second initial position and a difference between a current position of the moving rotation part and the first initial position.

In addition, according to an aspect 4 of the present invention, in the substrate holding device according to any one of the aspects 1 to 3, the detection unit may detect an amount of wear of the contact gripping parts.

In addition, according to an aspect 5 of the present invention, the substrate holding device according to any one of the aspects 1 to 4 may further include an alarm unit issuing an alarm when occurrence of wear of the contact gripping parts is detected.

To solve the problems described above, a method of detecting wear in a substrate holding device according to an aspect 6 of the present invention is a method of detecting wear of contact gripping parts in a substrate holding device that includes at least three rotation parts each having a contact gripping part that contacts a periphery portion of a substrate and rotates the substrate, and a moving mechanism moving at least one of the at least three rotation parts toward the substrate to cause the plurality of contact gripping parts to grip the substrate, and includes a first-initial-position acquisition process of acquiring a first initial position, which is a position of a moving rotation part, that is the rotation part moved by the moving mechanism, when the plurality of contact gripping parts grip the substrate in a state where the plurality of contact gripping parts are not worn, a current-position acquisition process of acquiring a current position of the moving rotation part after the first-initial-position acquisition process, and a detection process of detecting occurrence of wear of the contact gripping parts on the basis of a difference between a current position of the moving rotation part and the first initial position.

To solve the problems described above, a method of detecting wear in a substrate holding device according to an aspect 7 of the present invention is a method of detecting wear of contact gripping parts in a substrate holding device that includes at least three rotation parts each having a contact gripping part that contacts a periphery portion of a substrate and rotates the substrate, and a moving mechanism moving at least one of the at least three rotation parts toward the substrate to cause the plurality of contact gripping parts to grip the substrate, and includes a second-initial-position acquisition process of acquiring a second initial position, which is a position of the substrate when the plurality of contact gripping parts grip the substrate in a state where the plurality of contact gripping parts are not worn, a current-position acquisition process of acquiring a current position of the substrate after the second-initial-position acquisition process, and a detection process of detecting occurrence of wear of the contact gripping parts on the basis of a difference between a current position of the substrate and the second initial position.

### Effects of the Invention

According to the aspects of the present invention, it is possible to provide a substrate holding device and a method of detecting wear in a substrate holding device, capable of detecting wear of a contact gripping part for gripping and rotating a substrate.

### BRIEF DESCRIPTION OF DRAWINGS

FIG. 1 is a perspective view which shows a substrate cleaning device according to an embodiment of the present invention.

FIG. 2 is a schematic diagram which shows a substrate holding device according to the embodiment of the present invention.

FIG. 3 is a flowchart which shows an example of processing performed in the substrate cleaning device according to the embodiment of the present invention.

### DESCRIPTION OF EMBODIMENTS

### <Substrate Holding Device>

Hereinafter, a substrate holding device according to an embodiment of the present invention will be described on the basis of the drawings.

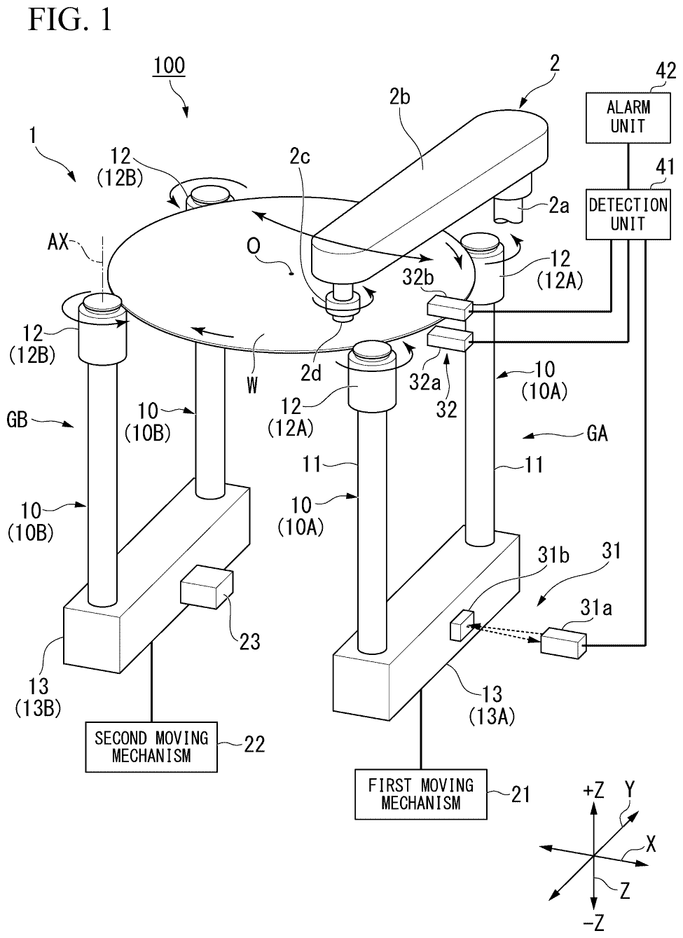

As shown in FIG. 1, a substrate holding device 1 according to the present embodiment includes at least three (four in the shown example) spindles 10, a first moving mechanism 21, and a second moving mechanism 22.

Each spindle 10 includes a pillar part 11 and a rotation part (a roller) 12 provided at a tip (an upper end) of the pillar part 11. Rotation part 12 has a rotation axis AX and is configured to be rotatable around the rotation axis AX. The plurality of (four in the shown example) rotation parts 12 are disposed to surround a circular substrate W from a radial outside of the substrate W.

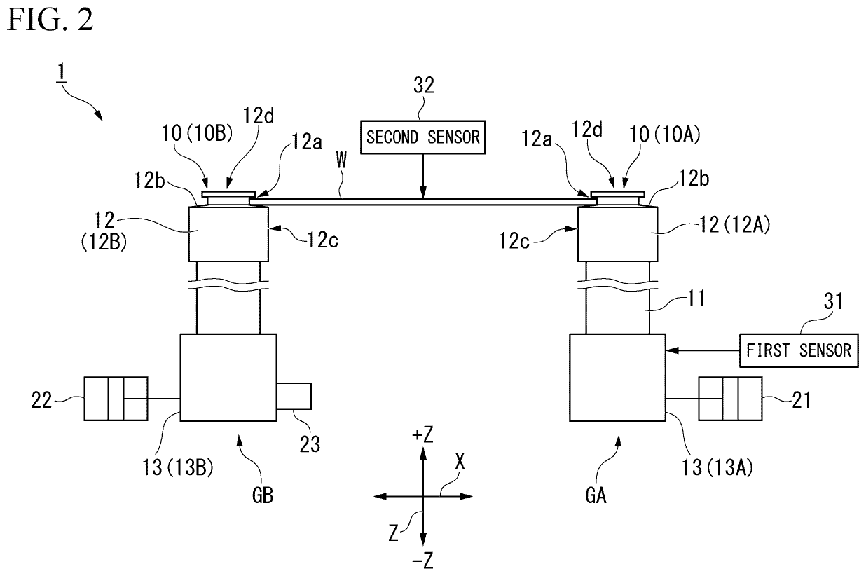

As shown in FIG. 2, the rotation part 12 includes a large diameter portion 12c and a small diameter portion 12d that has a smaller diameter than the large diameter portion 12c. The small diameter portion 12d is positioned at a tip (an upper end) of the spindle 10. The large diameter portion 12c is positioned between the small diameter portion 12d and the pillar part 11 in a longitudinal direction of the spindle 10.

Each rotation part 12 has a contact gripping part 12a. The contact gripping part 12a comes into contact with a periphery portion of the substrate W and rotates the substrate W around a center O of the substrate W. In the present embodiment, the contact gripping part 12a is a groove that opens on a side surface (outer circumferential surface) of the small diameter portion 12d. The contact gripping part 12a (rotation part 12) may be formed of an elastic material such as urethane rubber. The contact gripping part 12a is formed around an entire circumference of the rotation part 12. In the shown example, the periphery portion of the substrate W is fitted into the four contact gripping parts 12a of the four rotation parts 12 (also refer to FIG. 1). As a result, the four contact gripping parts 12a grip the substrate.

At least one of the four rotation parts 12 is a driving rotation part (a driving roller) whose rotation is driven by a power source such as a motor. When the driving rotation part rotates, the substrate W rotates around the center O due to a frictional force acting between the driving rotation part and the substrate W. The rotation parts 12 other than the driving rotation part are driven rotation parts (driven rollers). Unlike the driving rotation part, the driven rotation parts are not driven to rotate by a power source such as a motor. When the substrate W is rotated by the driving rotation part, the driven rotation parts rotate due to the frictional force acting between the substrate W and the driven rotation parts. In other words, the substrate holding device 1 is a device that holds the substrate while rotating the substrate. Note that, all four rotation parts 12 may be driving rotation parts.

The substrate holding device 1 is used, for example, with incorporated into a substrate cleaning device 100 equipped with a cleaning mechanism 2. Although detailed illustration is omitted, the substrate cleaning device 100 may include a load port and an EFEM which are ports for receiving and giving the substrate W, a transport machine which transports the substrate W, a drying unit which dries the cleaned substrate W, and a control unit which controls an overall operation of the substrate cleaning device 100 and the like.

The cleaning mechanism 2 in the shown example is a mechanism of cleaning a surface of the substrate W. This cleaning mechanism 2 has an arm 2b supported by an axis 2a, and an attachment part 2c provided at a tip of the arm 2b. The axis 2a is configured to be able to rise and fall and rotate, and the arm 2b also rises and falls and rotates depending on the rise and fall and rotation of the axis 2a. A sponge 2d is attached to the attachment part 2c. The attachment part 2c is configured to be able to rotate on its axis, and the sponge 2d also rotates on its axis depending on a time of the attachment part 2c. When the sponge 2d comes into sliding contact with the surface of the substrate W, the surface of the substrate W is cleaned. However, a configuration of the cleaning mechanism 2 is not limited to the configuration described above and may be changed as appropriate. For example, the cleaning mechanism 2 may be a mechanism of cleaning a back surface or a periphery portion (a bevel portion) of the substrate W. Moreover, the substrate holding device 1 does not have to be incorporated into the substrate cleaning device 100. For example, the substrate holding device 1 may be incorporated into a substrate polishing device for polishing the substrate W.

### Definitions of Directions

In the present embodiment, a direction parallel to a rotation axis of the substrate W (the rotation axis AX of the spindle 10) is referred to as an axial direction Z or an up and down direction Z. The axial direction Z may be, for example, a vertical direction parallel to gravity. A direction from the pillar part 11 toward the rotation part 12 in the axial direction Z is referred to as an upward direction and is represented as a +Z direction. A direction opposite to the upward direction is called a downward direction, and is represented as a −Z direction. A direction intersecting (for example, orthogonal to) the axial direction Z is referred to as a first direction X. The first direction X is also a direction in which the moving spindle group GA and the fixed spindle group GB to be described below face each other. A direction intersecting (for example, orthogonal to) both the axial direction Z and the first direction X is referred to as a second direction Y. In the first direction X, a direction toward the center O of the substrate W is referred to as an inward direction, and a direction away from the center O is referred to as an outward direction.

As shown in FIG. 1, a plurality of spindles 10 according to the present embodiment constitute two spindle groups GA and GB. Each spindle 10 belongs to one of the two spindle groups GA and GB. Hereinafter, one of these two spindle groups will be referred to as a moving spindle group GA, and the other as a fixed spindle group GB (a movement-restricted spindle group GB). The moving spindle group GA and the fixed spindle group GB are disposed to face each other in the first direction X.

Each of the spindle groups GA and GB includes two spindles 10. Hereinafter, the spindle 10 included in the moving spindle group GA will be referred to as a moving spindle 10A, and the spindle 10 included in the fixed spindle group GB will be referred to as a fixed spindle 10B (a movement-restricted spindle 10B). Lower ends of the spindles 10 belonging to the same spindle groups GA and GB are connected by a base 13. In the shown example, two moving spindles 10A are connected by one base 13, and two fixed spindles 10B are connected by another base 13. Hereinafter, the base 13 connecting the moving spindles 10A to each other is referred to as a first base 13A, and the base 13 connecting the fixed spindles 10B to each other is referred to as a second base 13B. In addition, the rotation part 12 of the moving spindle 10A is referred to as the moving rotation part 12A, and the rotation part 12 of the fixed spindle 10B is referred to as a fixed rotation part 12B (movement-restricted rotation part 12B).

The moving mechanisms 21 and 22 are mechanisms of moving the spindle 10. As shown in FIGS. 1 and 2, in the present embodiment, one moving mechanism is provided for each of the two spindle groups GA and GB. Hereinafter, a moving mechanism provided in the moving spindle group GA will be referred to as a first moving mechanism 21, and a moving mechanism provided in the fixed spindle group GB will be referred to as a second moving mechanism 22.

In the shown example, the first moving mechanism 21 moves the first base 13A in the first direction X. As a result, the two moving spindles 10A belonging to the moving spindle group GA and the first base 13A move integrally in the first direction X. Specifically, the first moving mechanism 21 presses the moving spindle 10A and the first base 13A inward in the first direction X. The first moving mechanism 21 may include, for example, an air cylinder that presses the first base 13A inward in the first direction X.

In the shown example, the second moving mechanism 22 moves the second base 13B in the first direction X. As a result, the two fixed spindles 10B belonging to the fixed spindle group GB and the second base 13B move integrally in the first direction X. Specifically, the second moving mechanism 22 presses the fixed spindle 10B and the second base 13B inward in the first direction X. The second moving mechanism 22 may include, for example, an air cylinder that presses the second base 13B inward in the first direction X.

As shown in FIGS. 1 and 2, a stopper 23 is provided on an inside of the second base 13B in the first direction X. The stopper 23 is fixed to a housing or the like in which the substrate holding device 1 is housed. By providing such a stopper 23, when the second moving mechanism 22 presses the second base 13B inward in the first direction X, the second base 13B abuts against the stopper 23. This restricts movement of the second base 13B, and the second base 13B and the fixed spindle 10B (a fixed rotation part 12B) connected to the second base 13B are fixed at predetermined positions. In other words, an inward movement of the fixed spindle 10B (a movement-restricted spindle 10B) and the fixed rotation part 12B (a movement-restricted rotation part 12B) are restricted by the stopper 23 in the first direction X.

On the other hand, such a stopper 23 is not provided around the first base 13A. Therefore, it is possible for the first moving mechanism 21 to freely press the first base 13A and the moving spindle 10A (moving rotation part 12A) connected to the first base 13A inward in the first direction X. In the present embodiment, the first moving mechanism 21 presses the first base 13A inward in the first direction X in a state where the second base 13B (the fixed rotation part 12B) is fixed by the second moving mechanism 22 and the stopper 23. As a result, the two contact gripping parts 12a of the two fixed rotation parts 12B and the two contact gripping parts 12a of the two moving rotation parts 12A grip the substrate W.

As shown in FIG. 2, in the present embodiment, an auxiliary surface 12b is formed on an upper surface of the large diameter portion 12c of each rotation part 12. When viewed in an axial direction Z, the auxiliary surface 12b has an annular shape surrounding the contact gripping part 12a. The auxiliary surface 12b prevents the substrate W from falling off the rotation part 12 when the contact gripping part 12a is caused to grip the substrate W or when the substrate W is removed from the contact gripping part 12a. Specifically, when the contact gripping part 12a is caused to grip the substrate W, the substrate W is first placed on the auxiliary surface 12b of each rotation part 12. Then, the moving mechanisms 21 and 22 narrow a gap between the rotation parts 12A and 12B, so that the substrate W slides on the auxiliary surface 12b and is eventually fitted into the contact gripping part 12a. Note that, in the shown example, the auxiliary surface 12b is inclined downward as it moves radially outward in the rotation part 12.

As the rotation and gripping of the substrate W as described above continues, the contact gripping part 12a is gradually worn. As shown in FIG. 1, the substrate holding device 1 according to the present embodiment further includes a first sensor 31, a second sensor 32, a detection unit 41, and an alarm unit 42 to detect the occurrence of such wear and inform an operator about it.

The first sensor 31 detects a position of the moving rotation part 12A. More specifically, the first sensor 31 in the present embodiment detects the position of the moving rotation part 12A in the first direction X. In the shown example, the first sensor 31 detects a position of the moving rotation part 12A indirectly by detecting a position of the first base 13A connected to the moving rotation part 12A. However, the first sensor 31 may directly detect the position of the moving rotation part 12A. The first sensor 31 outputs the detected position of the moving rotation part 12A to the detection unit 41.

As the first sensor 31, for example, a reflective displacement laser sensor may be used. In this case, as shown in FIG. 1, the first sensor 31 may have a sensor body 31a and a sensor dog 31b fixed to the first base 13A. The sensor body 31a and the sensor dog 31b are disposed to face each other in the first direction X. The sensor body 31a emits light toward the sensor dog 31b. The sensor dog 31b reflects the light emitted from the sensor body 31a toward the sensor body 31a. The sensor body 31a detects the position of the first base 13A in the first direction X on the basis of the light reflected from the sensor dog 31b.

The second sensor 32 detects a position of the substrate W. Note that, the “position of the substrate W” may be a position of the center O of the substrate W or a position of an outer periphery edge of the substrate W. The second sensor 32 outputs the detected position of the substrate W to the detection unit 41.

As the second sensor 32, for example, a sensor having a light-projecting unit 32a and a light-receiving unit 32b as shown in FIG. 1 may be used. The light-projecting unit 32a and the light-receiving unit 32b are disposed to face each other in the axial direction Z. The light-projecting unit 32a emits light toward the light-receiving unit 32b. The light-receiving unit 32b detects an intensity of the light emitted from the light-projecting unit 32a.

The light-projecting unit 32a and the light-receiving unit 32b are disposed so as to sandwich the periphery portion of the substrate W in the axial direction Z. As a result, at least a portion of the light emitted by the light-projecting unit 32a is blocked by the substrate W. When the position of the substrate W (the position of the outer periphery edge of the substrate W) changes, an amount of light blocked by the substrate W changes, and an amount of light emitted to the light-receiving unit 32b changes. The second sensor 32 detects the position of the substrate W on the basis of the amount of light emitted to the light-receiving unit 32b. Note that, a plurality of pairs (for example, three or more pairs) of the light-projecting unit 32a and the light-receiving unit 32b (sensor units) may also be disposed along the outer periphery edge of the substrate W.

It is preferable that the light-projecting unit 32a is provided below the substrate W (that is, a back surface side of the substrate W) and the light-receiving unit 32b is provided above the substrate W (that is, the surface side of the substrate W). This makes it possible to suppress deterioration of the surface of the substrate W caused by the light emitted by the light-projecting unit 32a.

Note that, it is preferable that the sensors 31 and 32 are disposed in positions that do not get in the way when the substrate W is cleaned. For example, the sensors 31 and 32 may be disposed in positions that do not allow the sensors to be exposed to cleaning liquid when the substrate W is cleaned.

The detection unit 41 acquires the position of the moving rotation part 12A output from the first sensor 31. The detection unit 41 acquires the position of the substrate W output from the second sensor 32. In addition, the detection unit 41 stores a first initial position and a second initial position. Here, the “first initial position” is a position of the moving rotation part 12A when the contact gripping parts 12a grip the substrate W in a state where the contact gripping parts 12a are not worn (that is, when the contact gripping parts 12a are new). The “second initial position” is a position of the substrate W when the contact gripping parts 12a grip the substrate W in the state where the contact gripping parts 12a are not worn (that is, the contact gripping parts 12a are new).

When wear occurs in the contact gripping part 12a, the position of the moving rotation part 12A and the position of the substrate W shift from the first initial position and the second initial position, respectively. For example, when the four contact gripping parts 12a are evenly worn, a pressing force of the first moving mechanism 21 causes the positions of the substrate W and the moving rotation part 12A to shift closer to the fixed rotation part 12B in the first direction X.

The detection unit 41 in the present embodiment detects the occurrence of wear in the contact gripping part 12a on the basis of current positions of the moving rotation part 12A and the substrate W and the first initial position and the second initial position stored in advance. More specifically, the detection unit 41 according to the present embodiment detects the occurrence of wear in the contact gripping part 12a on the basis of a difference between the current position of the moving rotation part 12A and the first initial position (hereinafter referred to as “a first difference”), and a difference between the current position of the substrate W and the second initial position (hereinafter referred to as “a second difference”). When the detection unit 41 detects the occurrence of wear, it outputs a predetermined detection signal to the alarm unit 42.

The detection unit 41 may detect the amount of wear of the contact gripping part 12a based on the first difference and the second difference. In other words, the detection unit 41 may quantitatively evaluate the amount of wear of the contact gripping part 12a.

Moreover, the detection unit 41 may detect whether wear is occurring in the contact gripping part 12a of the moving rotation part 12A or the contact gripping part 12a of the fixed rotation part 12B, based on the first difference and the second difference. For example, when the first difference occurs but the second difference does not occur (that is, when the position of the moving rotation part 12A changes but the position of the substrate W does not change), it is highly likely that the contact gripping part 12a of the fixed rotation part 12B is not worn, and only the contact gripping part 12a of the moving rotation part 12A is worn. Moreover, when both the first difference and the second difference occur and the first difference and the second difference are about the same, it is highly likely that the contact gripping part 12a of the moving rotation part 12A is not worn, and only the contact gripping part 12a of the fixed rotation part 12B is worn. In this manner, by providing both the first sensor 31 and the second sensor 32 on the substrate holding device 1, it is also possible to cause the detection unit 41 to detect uneven wear occurring among the plurality of contact gripping parts 12a. Note that, when both the first difference and the second difference occur and the second difference is about ½ of the first difference, it is highly likely that both the contact gripping part 12a of the moving rotation part 12A and the contact gripping part 12a of the fixed rotation part 12B are worn evenly. In cases where it is not necessary to detect uneven wear of the contact gripping part 12a or the like, the substrate holding device 1 may be provided with only one of the sensors 31 and 32.

The alarm unit 42 issues an alarm on the basis of the predetermined detection signal output from the detection unit 41. Note that, a type of the alarm is not particularly limited. The alarm issued by the alarm unit 42 may be sound, light, or a popup displayed on a monitor or the like.

Note that, by using the second sensor 32 to detect the position of the substrate W, whether the substrate W has been properly removed may be detected when the substrate W is removed from the substrate holding device 1. Specifically, when the gap between the rotation parts 12A and 12B is widened to remove the substrate W, the periphery portion of the substrate W may get caught by one of the contact gripping parts 12a, and the substrate W may be unintentionally pulled by the contact gripping part 12a. By detecting the position of the substrate W using the second sensor 32, it is also possible to detect such unintentional movement of the substrate W.

### <Wear Detection Method>

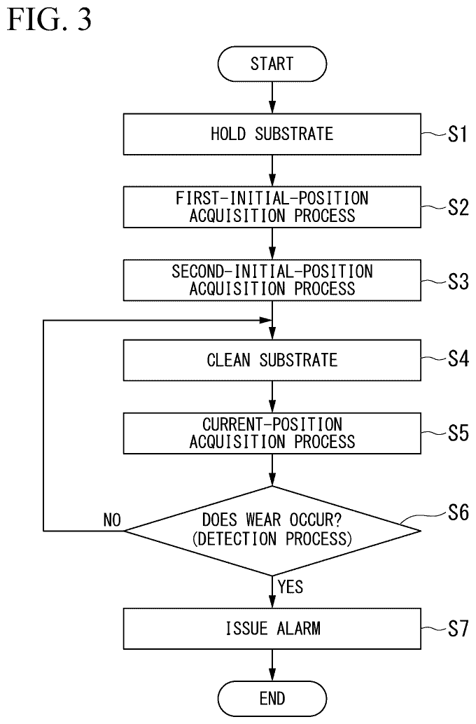

Next, a method of detecting wear of the contact gripping part 12a in the substrate holding device 1 configured as described above (a wear detection method) will be specifically described. FIG. 3 is a flowchart which shows an example of processing performed in the substrate holding device 1 according to the present embodiment.

(Step S1) First, the substrate holding device 1 is caused to hold the substrate W. Specifically, with the gap between the moving rotation part 12A and the fixed rotation part 12B sufficiently opened, the substrate W is placed on the auxiliary surface 12b of each rotation part 12. After that, the second moving mechanism 22 is driven. Then, a position of the fixed spindle 10B (the fixed rotation part 12B) is fixed by the stopper 23. In other words, a movement of the fixed spindle 10B (the fixed rotation part 12B) is restricted by the stopper 23. Thereafter, the first moving mechanism 21 is driven. The moving rotation part 12A is moved toward the substrate W (toward the fixed rotation part 12B) by an action of the first moving mechanism 21. As a result, the substrate W is gripped by the rotation parts 12A and 12B. In step S1, the contact gripping parts 12a that are not worn (that is, new products) are prepared for all the contact gripping parts 12a. Note that, in step S1, a jig having the same shape as the substrate W may be used instead of the substrate W. In step S1, the first moving mechanism 21 and the second moving mechanism 22 may be driven simultaneously. In this case, however, there is a possibility that the spindles 10A and 10B moved by the action of the moving mechanisms 21 and 22 push the substrate W against each other, causing the position of the substrate W to become unstable. For this reason, the configuration described above, that is, a configuration in which the second moving mechanism 22 is first driven to fix the fixed spindle 10B, and then the first moving mechanism 21 is driven, is more preferable.

(Step S2) After the contact gripping part 12a is caused to grip the substrate W, a first-initial-position acquisition process is performed. In the first-initial-position acquisition process, the first sensor 31 acquires the position of the moving rotation part 12A. The first sensor 31 outputs the acquired position of the moving rotation part 12A to the detection unit 41. The detection unit 41 stores the position of the moving rotation part 12A output from the first sensor 31 as the first initial position. That is, in the first-initial-position acquisition process, the first sensor 31 and the detection unit 41 acquire the first initial position.

(Step S3) Similarly, after the contact gripping part 12a is caused to grip the substrate W, a second-initial-position acquisition process is performed. In the second-initial-position acquisition process, the second sensor 32 acquires the position of the substrate W. The second sensor 32 outputs the acquired position of the substrate W to the detection unit 41. The detection unit 41 stores the position of the substrate W output from the second sensor 32 as the second initial position. That is, in the second-initial-position acquisition process, the second initial position is acquired by the second sensor 32 and the detection unit 41. Note that, when a jig is used instead of the substrate W in step S1, a position of the jig acquired by the second sensor 32 is acquired as the second initial position. In addition, an order of the first-initial-position acquisition process and the second-initial-position acquisition process is not particularly limited as long as they are performed after the step S1 described above.

(Step S4) After the first initial position and the second initial position are acquired, cleaning of a predetermined number of substrates W is performed using the cleaning mechanism 2 while the substrates W are rotated by the substrate holding device 1. In step S4, cleaning of only one substrate W may be performed, or cleaning of a plurality of substrates W (for example, hundreds or thousands of substrates W) may be performed. The number of substrates W to be cleaned in step S4 may be changed as appropriate. When the cleaning of a plurality of substrates W is performed, a replacement of the substrates W (that is, a removal of a substrate W from the substrate holding device 1 and holding of a new substrate W by the substrate holding device 1) is performed as appropriate.

(Step S5) After the cleaning of the predetermined number of substrates W is performed, a current-position acquisition process is performed. In the current-position acquisition process, the first sensor 31 again acquires the position (the current position) of the moving rotation part 12A. The first sensor 31 outputs the acquired current position of the moving rotation part 12A to the detection unit 41. Similarly, the second sensor 32 again acquires the position (the current position) of the substrate W. The second sensor 32 outputs the acquired current position of the substrate W to the detection unit 41.

(Step S6) After the current-position acquisition process is performed, a detection process is performed. In the detection process, the detection unit 41 detects the occurrence of wear in the contact gripping part 12a based on the first difference and the second difference described above. For example, the detection unit 41 detects the occurrence of wear in the contact gripping part 12a when the first difference or the second difference described above exceeds a predetermined threshold value. When the occurrence of wear in the contact gripping part 12a is not detected (NO in step S6), the processing of steps S4 to S5 is repeated. The number of times the processing of steps S4 to S5 is repeated may be determined at a discretion of an operator.

(Step S7) When the occurrence of wear in the contact gripping part 12a is detected (YES in step S6), the detection unit 41 outputs the predetermined detection signal to the alarm unit 42. The alarm unit 42 issues the alarm based on the detection signal output from the detection unit 41. An operator who confirms the alarm may perform the replacement of the rotation part 12 (the contact gripping part 12a). After the replacement of the rotation part 12 is performed, the processing of steps S1 to S7 may be repeated.

As described above, the substrate holding device 1 according to the present embodiment includes at least three rotation parts 12, each including the contact gripping part 12a that contacts the periphery portion of the substrate W to rotate the substrate W, the first moving mechanism (moving mechanism) 21 that moves at least one rotation part 12 (moving rotation part 12A) of the at least three rotation parts 12 toward the substrate W to cause the plurality of contact gripping parts 12a to grip the substrate W, the first sensor 31 directly or indirectly detecting the position of the moving rotation part 12A, which is the rotation part 12 moved by the first moving mechanism 21, and the detection unit 41 that stores the first initial position, which is the position of the moving rotation part 12A when the plurality of contact gripping parts 12a grip the substrate W in the state where the plurality of contact gripping parts 12a are not worn, and detects the occurrence of wear of the contact gripping parts 12a on the basis of the difference between the current position of the moving rotation part 12A and the first initial position.

The wear detection method according to the present embodiment is a method of detecting wear of the contact gripping part 12a in the substrate holding device 1, and includes the first-initial-position acquisition process of acquiring the first initial position, the current-position acquisition process of acquiring the current position of the moving rotation part 12A after the first-initial-position acquisition process, and the detection process of detecting the occurrence of wear of the contact gripping part 12a on the basis of the difference between the current position of the moving rotation part 12A and the first initial position.

With this configuration, it is possible to detect the occurrence of wear in the contact gripping part 12a based on a change in the position of the moving rotation part 12A. This makes it possible to optimize a replacement time of the rotation part 12.

Alternatively, the substrate holding device 1 according to the present embodiment includes at least three rotation parts 12, each including the contact gripping part 12a that contacts the periphery portion of the substrate W to rotate the substrate W, the first moving mechanism (moving mechanism) 21 that moves at least one of the at least three rotation parts 12 (the moving rotation part 12A) toward the substrate W to cause the plurality of contact gripping parts 12a to grip the substrate W, the second sensor 32 detecting the position of the substrate W, and the detection unit 41 that stores the second initial position, which is the position of the substrate W when the plurality of contact gripping parts 12a grip the substrate W in the state where the plurality of contact gripping parts 12a are not worn, and detects the occurrence of wear of the contact gripping parts 12a on the basis of the difference between the current position of the substrate W and the second initial position.

In addition, a wear detection method according to the present embodiment is a method of detecting wear of the contact gripping part 12a in the substrate holding device 1 described above, and includes the second-initial-position acquisition process of acquiring the second initial position, the current-position acquisition process of acquiring the current position of the substrate W after the second-initial-position acquisition process, and the detection process for detecting the occurrence of wear in the contact gripping part 12a on the basis of the difference between the current position of the substrate W and the second initial position.

With this configuration, it is possible to detect the occurrence of wear in the contact gripping part 12a on the basis of a change in the position of the substrate W. This makes it possible to optimize the replacement time of the rotation part 12.

The substrate holding device 1 according to the present embodiment includes both the first sensor 31 and the second sensor 32 described above, and the detection unit 41 detects the occurrence of wear of the contact gripping part 12a on the basis of the difference (the first difference) between the current position of the substrate W and the first initial position, and the difference (the second difference) between the current position of the moving rotation part 12A and the second initial position. With this configuration, it is possible to cause the detection unit 41 to detect occurrence of uneven wear among the plurality of contact gripping parts 12a.

The detection unit 41 may also detect the amount of wear of the contact gripping part 12a. With this configuration, it is possible to further promote optimization of the replacement time of the rotation part 12.

The substrate holding device 1 according to the present embodiment further includes the alarm unit 42 issuing the alarm when the occurrence of wear of the contact gripping part 12a is detected. This configuration makes it easier for an operator to notice the occurrence of wear, and it is possible to further promote the optimization of the replacement time of the rotation part 12.

A technical scope of the present invention is not limited to the embodiments described above, and various modifications may be made within a range not departing from the gist of the present invention.

For example, the configuration of the sensors 31 and 32 described above is merely an example, and may be modified as appropriate as long as they are capable of detecting the position of the moving rotation part 12A and the position of the substrate W, respectively. For example, in the shown example, the first sensor 31 is provided on an outer side of the first base 13A in the first direction X, but the position of the first sensor 31 may be modified as appropriate. The first sensor 31 may be provided on an inner side of the first base 13A in the first direction X, for example. The first sensor 31 may also be a sensor other than a reflective displacement laser sensor. Similarly, the second sensor 32 may be an image sensor, or the like. For example, when the second sensor 32 is an image sensor, the second sensor 32 may be disposed above the substrate W, and may measure the position of the substrate W by detecting an outer periphery edge of the substrate W.

In the embodiment described above, an air cylinder is given as an example of the moving mechanisms 21 and 22, but types of the moving mechanisms 21 and 22 are not limited to this. The moving mechanisms 21 and 22 may be, for example, a servo motor that engages with the spindle groups GA and GB or the like. In this case, the first sensor 31 may be a sensor that detects the number of rotations of the servo motor or the like.

In addition, the substrate holding device 1 does not necessarily have to include the alarm unit 42.

In addition, the number of rotation parts 12 (spindles 10) may be changed as appropriate, as long as they are capable of holding the substrate W.

Moreover, the substrate holding device 1 does not need to have a stopper 23. In this case, all of the rotation parts 12 are pressed toward the substrate W by the moving mechanisms 21 and 22. However, a configuration in which the fixed rotation part 12B is fixed by the stopper 23 as in the embodiment (that is, a configuration in which the moving spindle group GA and the fixed spindle group GB are separated) is preferable because it is easier to stabilize the position of the center O of the substrate W compared to a configuration in which the substrate holding device 1 does not have the stopper 23 (that is, a configuration in which all the rotation parts 12 are the moving rotation parts 12A).

In addition, it is possible to appropriately replace the components in the embodiments described above with known components within a range not departing from the gist of the present invention, and the embodiments described above and modified examples may be combined as appropriate.

### REFERENCE SIGNS LIST

1 Substrate holding device
12 rotation part
12A Moving rotation part
12a Contact gripping part
21 First moving mechanism
31 First sensor
32 Second sensor
41 Detection unit
42 Alarm unit
W Substrate

What is claimed is:

1. A substrate holding device comprising:
at least three rotation parts each including a contact gripping part that contacts a periphery portion of a substrate and rotates the substrate;
a moving mechanism moving at least one of the at least three rotation parts toward the substrate to cause the plurality of contact gripping parts to grip the substrate;
a first sensor directly or indirectly detecting a position of a moving rotation part, which is the rotation part moved by the moving mechanism; and
a detection unit storing a first initial position, which is a position of the moving rotation part when the plurality of contact gripping parts grip the substrate in a state where the plurality of contact gripping parts are not worn, and detecting occurrence of wear of the contact gripping parts on the basis of a difference between a current position of the moving rotation part and the first initial position.

2. A substrate holding device comprising:
at least three rotation parts each including a contact gripping part that contacts a periphery portion of a substrate and rotates the substrate;
a moving mechanism moving at least one of the at least three rotation parts toward the substrate to cause the plurality of contact gripping parts to grip the substrate;
a second sensor detecting a position of the substrate; and
a detection unit storing a second initial position, which is a position of the substrate when the plurality of contact gripping parts grip the substrate in a state where the plurality of contact gripping parts are not worn, and detecting occurrence of wear of the contact gripping parts on the basis of a difference between a current position of the substrate and the second initial position.

3. The substrate holding device according to claim 2, further comprising:
a first sensor directly or indirectly detecting a position of a moving rotation part, which is the rotation part moved by the moving mechanism,
wherein the detection unit stores a first initial position, which is a position of the moving rotation part when the plurality of contact gripping parts grip the substrate in a state where the plurality of contact gripping parts are not worn, and
the detection unit detects occurrence of wear of the contact gripping parts on the basis of a difference between a current position of the substrate and the second initial position and a difference between a current position of the moving rotation part and the first initial position.

4. The substrate holding device according to claim 1,
wherein the detection unit detects an amount of wear of the contact gripping parts.

5. The substrate holding device according to claim 1, further comprising:
an alarm unit issuing an alarm when occurrence of wear of the contact gripping parts is detected.

6. A method of detecting wear of contact gripping parts in a substrate holding device that includes at least three rotation parts each having a contact gripping part that contacts a periphery portion of a substrate and rotates the substrate, and a moving mechanism moving at least one of the at least three rotation parts toward the substrate to cause the plurality of contact gripping parts to grip the substrate, comprising:
acquiring a first initial position, which is a position of a moving rotation part, that is the rotation part moved by the moving mechanism, when the plurality of contact gripping parts grip the substrate in a state where the plurality of contact gripping parts are not worn;
acquiring a current position of the moving rotation part after the acquiring the first initial position; and
detecting occurrence of wear of the contact gripping parts on the basis of a difference between the current position of the moving rotation part and the first initial position.

7. A method of detecting wear of contact gripping parts in a substrate holding device that includes at least three rotation parts each having a contact gripping part that contacts a periphery portion of a substrate and rotates the substrate, and a moving mechanism moving at least one of the at least three rotation parts toward the substrate to cause the plurality of contact gripping parts to grip the substrate, comprising:
acquiring a second initial position, which is a position of the substrate when the plurality of contact gripping parts grip the substrate in a state where the plurality of contact gripping parts are not worn;
acquiring a current position of the substrate after the acquiring a second initial position; and
detecting occurrence of wear of the contact gripping parts on the basis of a difference between the current position of the substrate and the second initial position.

8. The substrate holding device according to claim 2,
wherein the detection unit detects an amount of wear of the contact gripping parts.

9. The substrate holding device according to claim 3,
wherein the detection unit detects an amount of wear of the contact gripping parts.

10. The substrate holding device according to claim 2, further comprising:
an alarm unit issuing an alarm when occurrence of wear of the contact gripping parts is detected.

11. The substrate holding device according to claim 3, further comprising:
an alarm unit issuing an alarm when occurrence of wear of the contact gripping parts is detected.

12. The substrate holding device according to claim 4, further comprising:
an alarm unit issuing an alarm when occurrence of wear of the contact gripping parts is detected.

13. The substrate holding device according to claim 8, further comprising:
an alarm unit issuing an alarm when occurrence of wear of the contact gripping parts is detected.

14. The substrate holding device according to claim 9, further comprising:
an alarm unit issuing an alarm when occurrence of wear of the contact gripping parts is detected.
